(19) United States
(12) Patent Application Publication
(10) Pub. No.: US 2006/0191868 A1
(43) Pub. Date: Aug. 31, 2006

(54) Concept for the wet-chemical removal of a sacrificial material in a material structure

(75) Inventors: Martin Franosch, Munich (DE); Andreas Meckes, Munich (DE); Klaus-Guenter Oppermann, Holzkirchen (DE)

Correspondence Address: Maginot, Moore & Beck;Chase Tower, Suite 3250, 111 Monument Circle, Indianapolis, IN, 46204, US

(73) Assignee: Infineon Technologies AG, Munchen (DE)

(21) Appl. No.: 11/346,605

(22) Filed: Feb. 2, 2006

(30) Foreign Application Priority Data
Feb. 2, 2005 (DE) 10 2005 004 795.5

(51) Int. Cl. B44C 1/22; H01L 21/302; C23F 1/00

(52) U.S. Cl. 216/83; 438/745

(57) ABSTRACT

In the inventive method for the wet-chemical removal of a sacrificial material in a material structure, there is first provided the material structure, wherein the material structure has a treatment region with the sacrificial material accessible through an opening. Subsequently, the sacrificial material is brought into contact with a wet-chemical treatment agent through the opening for the removal of the sacrificial material, wherein a mechanical vibration is generated in the wet-chemical treatment agent or in the wet-chemical treatment agent and the material structure during the contacting of the sacrificial material with the wet-chemical treatment agent.

### CROSS-REFERENCE TO RELATED APPLICATION

This application claims priority from German Patent Application No. 10 2005 004 795.5, which was filed on Feb. 2, 2005, and is incorporated herein by reference in its entirety.

### BACKGROUND OF THE INVENTION

1. Field of the Invention

The present invention relates to a concept for the effective and precise removal of a sacrificial material in a material structure by means of a wet-chemical treatment agent, and particularly to an effective contacting of a wet-chemical treatment agent with a sacrificial material through a relatively small access opening to a cavity structure to be generated to bring the sacrificial material into solution with the wet-chemical treatment agent and to remove it therewith to generate the desired cavity structure.

2. Description of the Related Art

Electronic devices requiring a clearance with respect to the circuit structure implemented in a substrate are often formed with an adjoining cavity in a semiconductor substrate. These electronic devices may, for example, be BAW filters (BAW=bulk acoustic wave), SAW filters (SAW=surface acoustic wave), sensors or actuators. Micro-electromechanical systems (MEMS), acceleration sensors or rotating rate sensors-whose functionality also requires a clearance with respect to the circuit structure may also be implemented with corresponding cavities.

For generating cavities in an electronic device and/or adjoining to the same, there are often used special etching and developing methods generally referred to as wet-chemical treatment methods in the following. For example, cavities may be generated in a wet-chemical way by so-called dip development and/or dip etching, wherein a material structure in which a cavity is to be produced is dipped into a wet-chemical treatment agent (solvent or etchant).

A further possibility to generate cavities for an electronic device is the so-called puddle development in which a wet-chemical treatment agent is sprayed onto a resist surface until the wet-chemical treatment agent completely covers the resist material surface. Depending on which regions of the resist material have been exposed or not, the wet-chemical treatment agent may now selectively remove the resist material (sacrificial material).

A further known procedure to generate cavities in a material structure is to spray the material structure to be treated with the wet-chemical treatment agent to achieve a free development or free etching of a cavity within the material structure.

With respect to FIGS. 2a-b, there will now, by way of example, be described a procedure known in the art for generating a cavity structure.

FIG. 2a shows a sectional view of a material structure 50 which may serve as starting point for generating a cavity structure by means of wet-chemical treatment. This material structure 50 comprises a substrate 52 on which there is provided, for example, an electromechanical structure 53. A sacrificial material 54 and a cover arrangement 56 having sidewall regions 56b and a top wall region 56a are arranged on the substrate 52, wherein several openings 58 are formed in the top wall region 56a of the cover arrangement 56. With the sidewall regions 56b, the top wall region 56a and together with the substrate 52, the cover arrangement 56 now defines two treatment regions 60a, 60b accessible through the openings 58, which, for manufacturing reasons, are filled with the sacrificial material 54 to be removed.

The material structure 50 illustrated in FIG. 2a may, for example, be obtained by depositing a layer of a negative resist material (negative varnish) on the substrate 52, which is subsequently selectively (for example also wavelength-selectively) exposed by means of various masks and various exposure wavelengths to obtain the material structure 50 with the sacrificial material 54 and the cover structure 56.

Here, the sacrificial material 54 represents, for example, an unexposed negative resist material, wherein the cover arrangement 56 with the sidewall regions 56b and the top wall region 56a represents, for example, exposed regions of the negative resist material.

The arrangement illustrated in FIG. 2a may, however, also be obtained correspondingly by means of a positive resist material (positive varnish), wherein in this case the exposed regions may form the sacrificial material 54 and the unexposed regions may form the cover arrangement 56 with the sidewall regions 56b and the top wall region 56a.

For example, an SU-8 resist material may be used as resist material. With respect to the material structure shown in FIG. 2a, it is further to be seen that there may also be used several resist material layers deposited on the substrate material 52 with successive exposure procedures to obtain the material structure 50 shown in FIG. 2a with the sacrificial material regions 54 and the cover arrangement 56.

According to typical wet-chemical treatment procedures, the provided material structure 50 and particularly the sacrificial material 54 is now brought into contact with a wet-chemical treatment agent 62, such as a solvent or an aqueous developer (for example PGMEA=propylene glycol methyl ether acetate), to bring the sacrificial material 54 into solution with the wet-chemical treatment agent 62, i.e. to remove the sacrificial material 54.

With respect to the material structure 50 shown in FIG. 2a, it is to be noted that the sacrificial material 54 to be removed in the treatment regions 60a, 60b is only accessible for the wet-chemical treatment agent 62 through the openings 58 of the cover arrangement 56 located in the top wall region 56a to bring the sacrificial material 54 into solution and to free the treatment regions 60a, 60b as cavities. The wet-chemical treatment rate (etching and/or developing rate) for freeing the cavity structures to be generated depends considerably on the cross-sectional area of the access openings 58 to the treatment regions 60a, 60b within the material structure 50. This means that smaller access openings 58 result in a lower wet-chemical treatment rate, whereby the time duration of the wet-chemical treatment for freeing the desired cavity structures is increased.

Based on a perspective sectional representation, FIG. 2b shows an example of a cavity structure generated by conventional wet-chemical treatment procedures, in which the sacrificial material 54 in the cavities 60a, 60b was only incompletely removed through the openings 58 due to an inhomogeneous wet-chemical treatment rate. As is to be seen from FIG. 2b, in prior art wet-chemical treatment procedures, it is essentially not possible to generate the desired cavities through small access openings 58 without residues, because these known procedures only allow a very slow and essentially inhomogeneous wet-chemical treatment rate of the sacrificial material 54 to be removed.

In the case of relatively small access openings to a cavity to be generated in a material structure, only a very small percentage of the total amount of the treatment agent, with respect to the total amount of the used wet-chemical treatment agents, can be brought into contact with the sacrificial material to be removed within the treatment regions (cavities) in conventional wet-chemical treatment procedures, so that there is often no sufficient exchange of the etchant within the cavity to be generated, whereby the sacrificial material to be removed may only be removed in a relatively slow and irregular way.

Due to the very long treatment duration of a cavity in the case of small access openings 58, the known wet-chemical treatment methods result in a relatively high medium consumption, because large amounts of the wet-chemical treatment agent 62 have to be used for freeing cavities through a small through-opening to bring a sufficient amount of wet-chemical treatment agents into contact with the sacrificial material within the treatment regions 60a, 60b.

In addition, due to the generally relatively small access openings to the cavity to be generated, there may often be obtained only relatively inaccurate and rough structures and/or dimensions of the resulting cavity, because the wet-chemical treatment agent entering through the relatively small access openings cannot spread homogeneously in the material structure, so that residues of the sacrificial material that was actually to be removed often remain in the cavity.

Since essentially no homogeneous etching rates may be obtained via the small access openings in the material structure leading to the cavity to be produced, there may not only occur insufficient etching with sacrificial material residues remaining in the cavities according to prior art, but often also undesired overetchings at the same time, due to the required long treatment duration, at other places on the material structure 50, wherein regions of the material structure 50 are attacked by the wet-chemical treatment agents 62 and are removed unwantedly.

Thus, the wet-chemical treatment procedures for freeing cavities in a material structure known in the art have often proved to be unsuitable to free complex and complicated cavity structures through small access openings in a precise way.

### SUMMARY OF THE INVENTION

It is the object of the present invention to provide an improved concept for the wet-chemical treatment of a material structure, wherein a wet-chemical removal of a sacrificial material in the material structure and particularly the generation of a cavity for an electronic device may be performed both in a more efficient and a more precise way.

In accordance with a first aspect, the present invention provides a method for the wet-chemical removal of a sacrificial material in a material structure, having the steps of providing the material structure, wherein the material structure has a treatment region with the sacrificial material accessible through an opening; contacting the sacrificial material with a wet-chemical treatment agent through the opening for the removal of the sacrificial material; and generating a mechanical vibration in the wet-chemical treatment agent or in the wet-chemical treatment agent and the material structure during the contacting of the sacrificial material with the wet-chemical treatment agent.

In accordance with a second aspect, the present invention provides a device for the wet-chemical removal of a sacrificial material in a material structure, wherein the material structure has a treatment region with the sacrificial material accessible through an opening, the device having a unit for contacting designed to bring the wet-chemical treatment agent into contact with the sacrificial material through the opening to remove the sacrificial material; and a launching unit designed to launch a mechanical vibration into the wet-chemical treatment agent or into the wet-chemical treatment agent and into the material structure, while the sacrificial material is in contact with the wet-chemical treatment agent.

The present invention is based on the finding that, in the inventive concept for the wet-chemical removal of a sacrificial material in a material structure, a mechanical and/or acoustic vibration excitation or launching by means of sound, such as ultrasonic or megasonic excitation, is generated in the wet-chemical treatment agent or in the wet-chemical treatment agent and the material structure during the contacting of the sacrificial material, for example through a relatively small access opening in the material structure, with the wet-chemical treatment agent. Here, the acoustic excitation in the wet-chemical treatment agent or in the wet-chemical treatment agent and the material structure has the result that, with respect to a determined time duration, a larger number of particles of the wet-chemical treatment agent may be brought into contact with the sacrificial material to be removed in the material structure and thus the sacrificial material to be removed may be brought into solution by the wet-chemical treatment agent in a more efficient and fast way.

The inventive procedure thus increases the wet-chemical treatment rate, i.e. the etching and/or developing rate, of the sacrificial material to be removed, which, in particular, has the result that the time duration required to remove the sacrificial material in the material structure and to form the desired cavity decreases considerably with respect to procedures known in the art. In addition, a considerably more homogeneous wet-chemical treatment rate of the sacrificial material may also be achieved by the inventive procedure. The more efficient wet-chemical treatment rate obtained according to the present invention and its improved homogeneity further causes the cavities that have been etched free to have considerably more precise structures in which there remain essentially no sacrificial material residues, while, at the same time, an unwanted overetching of the treated material structures may be prevented.

Thus the inventive procedure allows freeing very complex and complicated structures, particularly when they are accessible only through relatively small access openings. At the same time, the precision of the obtained structures (particularly cavity structures) may be obtained with a simultaneously very low medium consumption for wet-chemical treatment agents, such as etchants and developers.

### BRIEF DESCRIPTION OF THE DRAWINGS

Preferred embodiments of the present invention will be explained in more detail in the following with respect to the accompanying drawings, in which:

FIGS. 1a-1b show a schematic sectional view of a multi-layer structure with which the inventive concept for generating a cavity according to the present invention is illustrated, and a perspective sectional representation of a cavity structure actually obtained according to the inventive concept; and

FIGS. 2a-2b show a schematic sectional view of a multi-layer structure with which a known procedure for generating a cavity according to prior art is illustrated, and a perspective sectional representation of a cavity structure actually obtained according to prior art.

### DESCRIPTION OF THE PREFERRED EMBODIMENTS

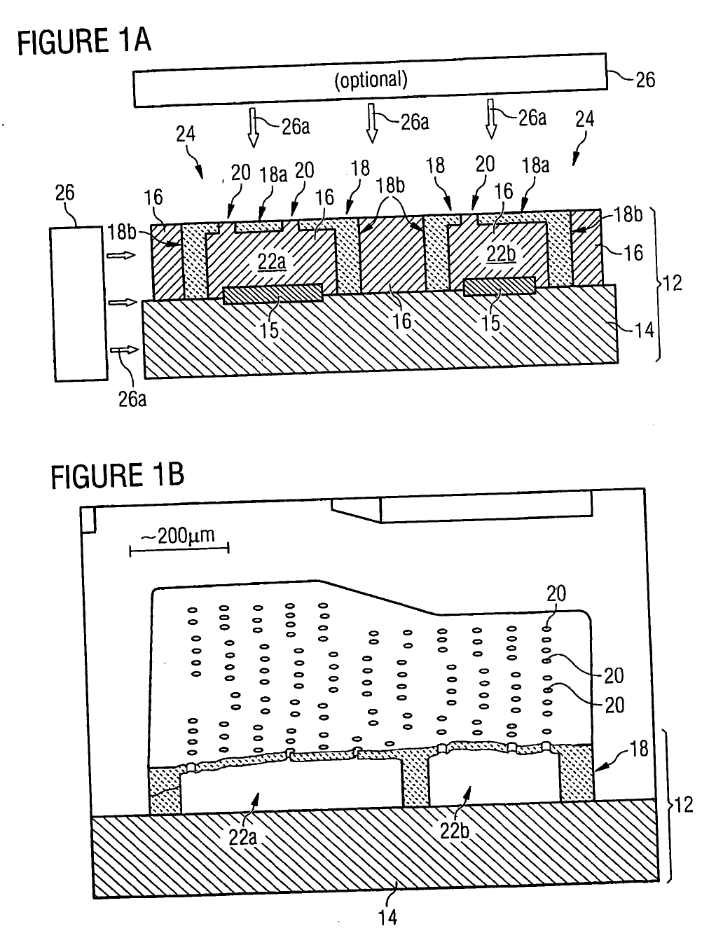

In the following, there will now be explained an inventive procedure for the wet-chemical removal of a sacrificial material in a material structure by way of example with respect to FIGS. 1a-b.

In the inventive method for the wet-chemical removal of a sacrificial material in a material structure, there is first provided a material structure 12, wherein this material structure 12 comprises a substrate 14 on which there is provided, for example, an electrical, electronic, mechanical and/or electromechanical structure 15. A sacrificial material 16 and a cover arrangement 18 having sidewall regions 18b and a top wall region 18a are further arranged on the substrate 14, wherein one or more openings 20 are formed in the top edge region 18a of the cover arrangement 18. With the sidewall regions 18b, the top wall region 18a and together with the substrate 14, the cover arrangement 18 now defines one or more treatment regions 22a, 22b accessible through the openings 20 which (for example due to manufacturing reasons) are filled at least partially with the sacrificial material 16 to be removed. As illustrated in FIG. 1a, the sacrificial material 16 may also be present in the opening 20 through the top wall region 18a (for example due to manufacturing reasons).

With respect to the present invention, it should be noted that one or more treatment regions 22a, 22b may be provided, each with only a single opening 20 or also several openings 20.

The material structure 12 illustrated in sectional view in FIG. 1a may, for example, be obtained according to the procedure discussed above with negative or positive resist materials (varnish) which are selectively (for example also wavelength-selectively) exposed by means of various masks and various exposure wavelengths.

In the inventive method, the provided material structure 12 and particularly the sacrificial material 16 is now brought into contact with a wet-chemical treatment agent 24, such as a solvent or an aqueous developer (for example PGMEA=propylene glycol methyl ether acetate), to bring the sacrificial material 16 into solution with the wet-chemical treatment agent 24 and thus to remove the sacrificial material 16. Through the opening and/or openings 20 of the cover arrangement 18 located in the top wall region 18a, the sacrificial material 16 to be removed in the treatment regions 22a, 22b is now further brought into solution by means of the wet-chemical treatment agent 24 to essentially free the treatment regions 22a, 22b accessible through the openings 20 as cavities.

According to the present invention, the material structure 12 may be brought into contact with the wet-chemical treatment agent for example by means of a so-called dip treatment (dip development and/or dip etching), by means of a so-called puddle treatment (puddle development and/or puddle etching), or by means of a spray treatment (spray development and/or spray etching) to bring the sacrificial material 16 to be removed into solution with the wet-chemical treatment agent. However, it should be noted with respect to the present invention that essentially all known wet-chemical treatment processes (development and/or etching processes) may be used for performing the inventive concept for the wet-chemical removal of the sacrificial material 16 in the material structure 12, wherein essentially also all suitable and known wet-chemical treatment agents, i.e. solvents, aqueous developers or wet-chemical etchants, may be used for this.

According to the present invention, an arrangement 26 for generating mechanical and/or acoustic vibrations is now associated with the provided material structure 12, wherein this arrangement may comprise an acoustic source 26 or optionally a plurality of acoustic sources 26 according to the invention.

The acoustic source 26 is arranged with respect to the material structure 12 to be treated so that the mechanical and/or acoustic vibration 26a may be launched as efficiently as possible into the material structure 12. As illustrated in FIG. 1a, for example for a dip treatment of the material structure 12, the acoustic source 26 may be arranged laterally with respect to the material structure 12 to be treated (the wafer with the material structure 12), wherein, for a puddle treatment or a spray treatment of the material structure 12, the acoustic source 26 may be arranged, for example, in parallel to the material structure 12 (to a wafer). With respect to the present invention, it should be appreciated that the spatial association between the material structure 12 to be treated and the acoustic source 26 (and/or sources 26) is only to be designed such that the mechanical and/or acoustic vibration 26a is launched as effectively as possible into the wet-chemical treatment agent 24 affecting the material structure 12.

According to the present invention, there is now generated a mechanical and/or acoustic vibration 26a in the wet-chemical treatment agent 24 or in the wet-chemical treatment agent and the material structure 12 during the contacting of the sacrificial material with the wet-chemical treatment agent by means of the acoustic source(s) 26, which is, for example, implemented as an ultrasonic or megasonic source.

According to the present invention, there is thus achieved a stronger relative movement between the material structure 12 with the sacrificial material 16 to be removed and the particles of the wet-chemical treatment agent 24 by launching the mechanical and/or acoustic vibration in the wet-chemical treatment agent or in the wet-chemical treatment agent and the material structure 12. According to the invention, the material and/or the materials of the sacrificial layer 16 may thus be brought into solution with the wet-chemical treatment agent 24 very efficiently. The acoustic source 24 may, for example, provide a mechanical and/or acoustic vibration (and/or vibrations) in a frequency range between 10 kHz and 10 MHz and preferably in a frequency range from 20 kHz to 5 MHz.

Since currently there are commercially available mainly acoustic sources for the use in the ultrasonic range, which is, for example, in a frequency range from 20 kHz to 50 kHz and preferably in a frequency range around 40 kHz, and for the use in the megasonic range, which is, for example, in a frequency range from about 500 kHz to 5 MHz and preferably in a frequency range around 920 kHz, such acoustic sources (for example ultrasonic transducers or megasonic transducers) may be used preferably, i.e. without larger effort, in the inventive method for the wet-chemical removal of the sacrificial material in the material structure 12. However, it is to be noted that acoustic sources with essentially any vibration frequencies in the above frequency range may be used according to the invention to obtain the advantageous effects in freeing cavities.

With respect to the present invention, it should further be noted that, in wet-chemical treatment processes (for example dip developments and/or dip etchings), there may be done, for example, a launching of the mechanical vibration into the wet-chemical treatment agent or into the wet-chemical treatment agent and the material structure 12 during the contacting of the sacrificial material 16 with the wet-chemical treatment agent, wherein the launching is preferably done into the liquid, i.e. the wet-chemical treatment agent. In spray or puddle development, too, the launching is normally done into the liquid film over the wafer and/or over the material structure 12 to be treated. Optionally, a vibration may also be launched into the cavity cap of the material structure. This generates higher particle velocities and pressure variations, for example in the form of shock waves, in the liquid, which may even result in explosions at the interface to the solid body (cavitation).

FIG. 1b shows a perspective sectional view of the material structure 12 after the inventive method for the wet-chemical treatment of the sacrificial material 16 in the material structure 12 has been performed. As can clearly be seen from FIG. 1b, particularly the sacrificial material 16 may be completely removed, i.e. without residues, from the treatment regions 22a, 22b according to the inventive method to obtain the desired cavity 22 within the cover arrangement 18.

With respect to the illustrations in FIGS. 1a-b, it should be noted that there may be provided only a single or also several treatment regions 22a, 22b, each having only a single or also several openings 20, wherein the single opening and/or the several openings 20 may optionally be closed subsequently to the wet-chemical removal of the sacrificial material 16 in the material structure 12 to form a closed off cavity within the cover arrangement 18. The closing of the cavity 22 may, for example, be done by deposition a further resist material and/or a further resist layer (for example negative resist material), exposure and subsequent development.

In connection with the present invention, it should be noted that the term “cavity” and/or “cavity structure” is thus essentially to be understood as a freed, but mostly enclosed region which may be spatially closed off for example by closing the one access opening or the several access openings.

As becomes apparent from the above discussion, the inventive concept for the wet-chemical removal of the sacrificial material 16 in the material structure 12 may, for example, be used very advantageously for the generation of so-called WLP arrangements (WLP=wafer level package), in which a large number of cover arrangements 18 are provided on a semiconductor wafer. These cover arrangements may particularly provide a protective function for the electrical, electronic, mechanical or electromechanical structure 15 arranged within and/or on the substrate 14, for example a semiconductor wafer, by providing a cavity in WLP arrangements.

In the above discussion, the inventive concept for the wet-chemical removal of a sacrificial material in a material structure was shown essentially with respect to the developing of a sacrificial material 16 that is present in the form of an exposed or unexposed photoresist material. However, the inventive concept may equally be applied to wet-chemical etching processes via small access openings with the goal of producing a cavity.

However, it should be appreciated with respect to the inventive concept that this concept may essentially be advantageously applied to all procedures for removing (any) sacrificial materials by means of wet-chemical treatment agents included in the term wet-chemical treatment processes, particularly also in the semiconductor production on the wafer level, such as in basin development and one-slice development.

Thus, the inventive concept for the wet-chemical removal of a sacrificial material in a material structure is particularly also useable in etching free cavities in the production of a WLP housing with an SU-8 resist material and a copper sacrificial layer (cf. German patent application DE 10316776.5 by the same applicant as the present invention. There, the underlying sacrificial layer of copper is etched out with an aqueous etching medium through a perforated cap and/or a perforated cover arrangement of an SU-8 resist material, wherein the freeing etching of the cavity may be considerably accelerated by the inventive generating of a mechanical vibration in the material structure or the wet-chemical treatment agent during the contacting of the sacrificial material with the wet-chemical treatment agent.

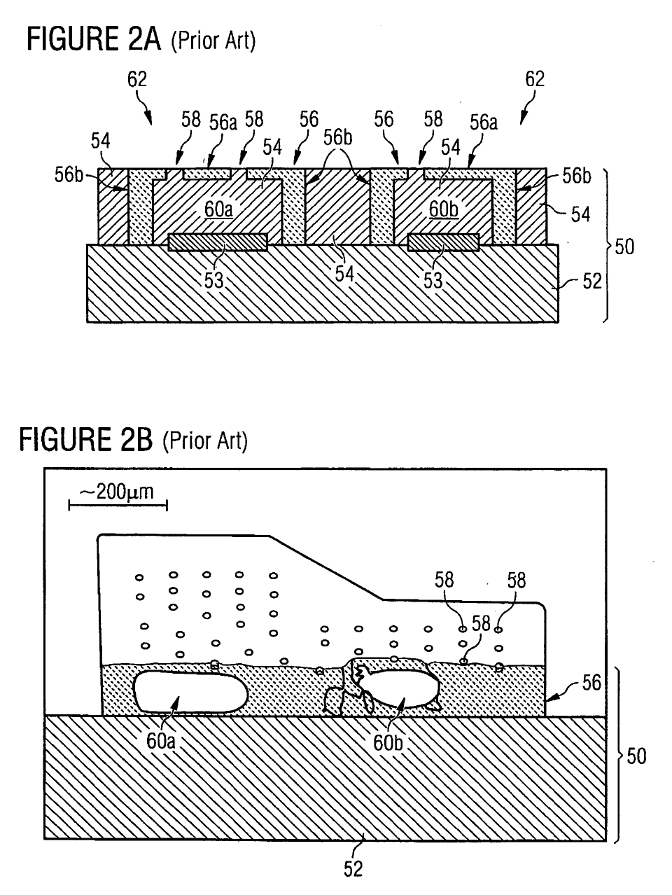

As can particularly be seen from the perspective sectional illustration of FIG. 1b, the desired cavities may be obtained in a very precise and efficient way by means of the inventive procedure for the wet-chemical removal of a sacrificial material in a material structure, in contrast to prior art (cf. FIG. 2b), because the material of the sacrificial layer to be removed may be removed from the treatment region in a significantly shorter time duration in a very homogeneous way and without residues.

With respect to the comparison of the resulting cavity regions 60a, 60b of FIG. 2b obtained by known production methods and the cavity structures 22a, 22b of FIG. 1b obtained according to the invention, which were obtained according to the inventive concept for the wet-chemical removal of a sacrificial material in a material structure, it is to be noted that both material structures illustrated in FIGS. 1b and 2b have been subjected to the same wet-chemical processes and have been subjected to the wet-chemical treatment agent for the same time duration.

The present invention thus provides an improved procedure for the accelerated wet-chemical removal of sacrificial layers of any kind, such as polymer materials, oxide materials, nitride materials, metals, semiconductors, metal alloys, etc., particularly also through relatively small access openings to a treatment region accessible through these small access openings, with the goal of generating a freed cavity as precisely as possible.

In summary, it can be stated that, according to the present invention, an acoustic excitation in the wet-chemical treatment agent and/or to the material structure to be wet-chemically treated and to the substrate containing the material structure (for example a semiconductor wafer) is now induced in addition to the wet-chemical treatment of a material structure.

According to the present invention, it may be, for example, ultrasonic or also megasonic, wherein the acoustic excitation may be launched into the material structure and/or into the wet-chemical treatment agent itself. According to the invention this has the result that the material and/or the materials of the sacrificial layer may be brought into solution with the wet-chemical treatment agent significantly faster than in prior art. According to the present invention, the sacrificial layer to be removed may thus be removed from the treatment regions (for example cavities) in a very precise and efficient way.

While this invention has been described in terms of several preferred embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

What is claimed is:

1. A method for the wet-chemical removal of a sacrificial material in a material structure, comprising:
providing the material structure, wherein the material structure comprises a treatment region with the sacrificial material accessible through an opening;
contacting the sacrificial material with a wet-chemical treatment agent through the opening for the removal of the sacrificial material; and
generating a mechanical vibration in the wet-chemical treatment agent or in the wet-chemical treatment agent and the material structure during the contacting of the sacrificial material with the wet-chemical treatment agent.

2. The method according to claim 1, wherein the step of generating the mechanical vibration in the material structure comprises a step of launching the mechanical vibration into the material structure.

3. The method according to claim 1, wherein the step of generating the mechanical vibration in the wet-chemical treatment agent comprises a step of launching the mechanical vibration into the wet-chemical treatment agent.

4. The method according to claim 1, wherein the sacrificial material is brought into solution with the wet-chemical treatment agent by the step of contacting.

5. The method according to claim 1, wherein the material structure comprises a substrate region, a cover arrangement with sidewall regions and a top wall region, wherein the treatment region is surrounded by the cover arrangement and the substrate.

6. The method according to claim 1, wherein the mechanical vibration has a frequency in a range between 10 kHz and 10 MHz.

7. The method according to claim 6, wherein the mechanical vibration preferably has a frequency in a range between 20 kHz and 50 kHz or in a range between 800 kHz and 1.2 MHz.

8. The method according to claim 1, wherein the sacrificial material comprises a material from the following group, wherein the group comprises a semiconductor material, a plastic material, a polymer material, a metal, a metal alloy, a resist material, preferably an SU-8 resist material, an oxide material, a nitride material and/or combinations thereof.

9. The method according to claim 1, wherein the material structure is arranged on a semiconductor wafer.

10. The method according to claim 10, wherein a plurality of material structures are arranged on the semiconductor wafer.

11. The method according to claim 1, wherein the step of contacting the sacrificial material with the wet-chemical treatment agent comprises one of the following substeps:
distributing the wet-chemical treatment agent on the material structure; or
spraying the wet-chemical treatment agent onto the material structure; or
dipping the material structure into the wet-chemical treatment agent.

12. The method according to claim 1, wherein the wet-chemical treatment agent comprises a solvent, an aqueous developer or a wet-chemical etchant.

13. A device for the wet-chemical removal of a sacrificial material in a material structure, wherein the material structure comprises a treatment region with the sacrificial material accessible through an opening, comprising:
a unit for contacting designed to bring the wet-chemical treatment agent into contact with the sacrificial material through the opening to remove the sacrificial material; and
a launching unit designed to launch a mechanical vibration into the wet-chemical treatment agent or into the wet-chemical treatment agent and into the material structure, while the sacrificial material is in contact with the wet-chemical treatment agent.

14. A method for the wet-chemical removal of a sacrificial material in a material structure, the material structure comprising a first region with the sacrificial material accessible through an opening comprising:
a) contacting the sacrificial material with a wet-chemical treatment agent through the opening for the removal of the sacrificial material; and
b) generating, during the at least part of the contacting of the sacrificial material with the wet-chemical treatment agent, a mechanical vibration in at least one of the group consisting of the wet-chemical treatment agent and the material structure.

15. The method according to claim 14, wherein step b) comprises generating the mechanical vibration in the material structure.

16. The method according to claim 14, wherein step b) further comprises generating the mechanical vibration in the wet-chemical treatment agent.

17. The method according to claim 14, wherein the sacrificial material is brought into solution with the wet-chemical treatment agent by the step of contacting.

18. The method according to claim 14, wherein the material structure comprises a substrate region, a cover arrangement with sidewall regions and a top wall region, and wherein the treatment region is surrounded by the cover arrangement and the substrate.
